(19) United States
(12) Patent Application Publication
(10) Pub. No.: US 2004/0163843 A1
(43) Pub. Date: Aug. 26, 2004

(54) Multi-chip package with soft element and method of manufacturing the same

(76) Inventors: Dong-Kil Shin, Gyeonggi-do (KR); Dong-Ho Lee, Gyeonggi-do (KR); Ho-Jeong Moon, Chungcheongnam-do (KR); Sang-Young Kim, Chungcheongnam-do (KR)

Correspondence Address: MARGER JOHNSON & McCOLLOM, P.C., 1030 S.W. Morrison Street, Portland, OR, 97205, US

(21) Appl. No.: 10/772,651

(22) Filed: Feb. 4, 2004

(30) Foreign Application Priority Data
Feb. 22, 2003 (KR) 2003-11209

(51) Int. Cl. H05K 1/00

(52) U.S. Cl. 174/254

(57) ABSTRACT

According to embodiments of the invention, a multi-chip package includes a soft element which is more elastic and flexible than the encapsulant on the sides or upper surface of the chips. Therefore, stress concentration and chip crack is prevented by ensuring vertical mobility of the chips.

### CROSS REFERENCE TO RELATED APPLICATIONS

This application claims priority from Korean Patent Application No. 10-2003-0011209, filed on Feb. 22, 2003, in the Korean Intellectual Property Office, the disclosure of which is incorporated herein by reference in its entirety.

### BACKGROUND OF THE INVENTION

1. Field of the Invention

This disclosure relates to semiconductor devices, and more particularly, to multi-chip packages and methods of manufacturing the same.

2. Description of the Related Art

There has been an increasing interest in multi-chip packages having a stacked structure of multiple chips so as to satisfy the demand of consumers who want to have small size, large capacity, and multi-functional memories. However, due to complicated structures relative to conventional single chip packages, there are various reliability problems related to multi-chip packages.

FIG. 1 shows a conventional multi-chip package having a chip-on-chip structure in which two chips are vertically stacked. Referring to FIG. 1, a first chip 30 is bonded on a substrate 10 with an adhesive 20 and a second chip 40 is bonded on the first chip 30 with the adhesive 20. The stacked chip structure is encapsulated with an epoxy molding compound (EMC) 50 that is a representative epoxy based mold resin. A reference numeral 60 represents bonding wires such as gold wires that connect bond pads of the first and second chips 30 and 40 to bond fingers of the substrate 10. A reference numeral 70 represents solder balls used for connecting the package to the external circuit. However, in such a multi-chip package structure, due to a thermal load by the adhesive 20 used for chip stacking, chip deformation frequently occurs both in a horizontal direction and in a vertical direction, thereby causing chip crack.

First, with respect to a horizontal direction mode of the chip deformation, as shown in FIG. 2, contraction of the package occurs. At the same time, the global thermal mismatch causes warpage of the first and second chips 30 and 40, due to a tendency to maintain balance between the contractive force 52 of the EMC 50 and the contractive force 12 of the substrate 10. A vertical direction mode of the chip deformation is caused by the contractive force 22 of the adhesive 20 upon cooling of the package, as shown in FIG. 3. Due to the contractive force 22 of the adhesive 20, the first and second chips 30 and 40 tend to be located approximate to each other. Since a common adhesive is a relatively weak material, even a small force of a vertical direction mode applied to thin chips can cause great deformation of the adhesive. Meanwhile, the EMC 50 that encapsulates the first and second chips 30 and 40 has a low thermal expansion coefficient and a hard strength, thereby strongly constricting the edge portions of the first and second chips 30 and 40. For that reason, the edge portions of the first and second chips 30 and 40 are greatly warped upon cooling of the package, and a stress is concentrated on the edge portions of the first and second chips 30 and 40, thereby creating vulnerable portions 32 and 42, as shown in FIG. 3. Furthermore, chip crack may be caused. In particular, in a multi-chip package having a stacked structure of the same types of chips, chip crack is frequently caused.

### SUMMARY OF THE INVENTION

A multi-chip package according to some embodiments of the invention includes at least two semiconductor chips vertically mounted on a substrate and encapsulated with an encapsulant such as a mold resin and a soft element that is more elastic and flexible than the encapsulant located at an interface between at least one of the at least two semiconductor chips and the encapsulant.

### BRIEF DESCRIPTION OF THE DRAWINGS

The above and other features and advantages of the invention will become more apparent by describing in detail exemplary embodiments thereof with reference to the attached drawings.

FIG. 1 is a cross-cross-sectional view illustrating a conventional multi-chip package.

FIG. 2 is a cross-cross-sectional view illustrating the horizontal mode thermal deformation and global warpage of the package of FIG. 1.

FIG. 3 is a cross-cross-sectional view illustrating the vertical mode thermal deformation of the package of FIG. 1.

FIG. 4A is a schematic plan view illustrating a multi-chip package including a soft element on a side of semiconductor chips according to some embodiments of the invention.

FIG. 4B is a cross-cross-sectional view taken along line B-B′ of FIG. 4A.

FIG. 5A is a schematic plan view illustrating a multi-chip package including a soft element on a side of semiconductor chips according to some other embodiments of the invention.

FIG. 5B is a cross-cross-sectional view taken along line B-B′ of FIG. 5A.

FIG. 6A is a schematic plan view illustrating a multi-chip package including a soft element on a side of semiconductor chips according to some embodiments of the invention.

FIG. 6B is a cross-sectional view taken along line B-B′ of FIG. 6A.

FIG. 7A is a schematic plan view illustrating a multi-chip package including a soft element on a side of semiconductor chips according to some other embodiments of the invention.

FIG. 7B is a cross-sectional view taken along line B-B′ of FIG. 7A.

FIG. 8A is a schematic plan view illustrating a multi-chip package including a soft element on a side of semiconductor chips according to some embodiments of the invention.

FIG. 8B is a cross-sectional view taken along line B-B′ of FIG. 8A.

FIG. 9A is a schematic plan view illustrating a multi-chip package including a soft element on an upper surface of the uppermost semiconductor chip according to some other embodiments of the invention.

FIG. 9B is a cross-sectional view taken along line B-B′ of FIG. 9A.

FIG. 10 is a perspective view that illustrates a stress simulation result of the package of FIG. 1.

FIG. 11 is a perspective view that illustrates a stress simulation result of a first chip in the package of FIG. 1.

FIG. 12 is a perspective view that illustrates a stress simulation result of a first chip in the package of FIG. 8.

FIG. 13 is a perspective view that illustrates a stress simulation result of a first chip in the package of FIG. 6.

### DETAILED DESCRIPTION OF THE INVENTION

Hereinafter, preferred embodiments of a multi-chip package and a method for manufacturing the same according to the present invention will be described with reference to the accompanying drawings.

A multi-chip package according to embodiments of the invention has a chip-on-chip structure in which two semiconductor chips, such as a flash memory chip and a SRAM chip, are vertically stacked on a substrate using an adhesive. Such a chip structure is encapsulated with an encapsulant such as an epoxy-based mold resin such as an epoxy molding compound (EMC) or silicon-based mold resin. The multi-chip package includes a soft element which is more elastic and flexible than the mold resin on an interface of the semiconductor chips and the mold resin. The multi-chip package may be a fine pitch ball grid array (FBGA) package with a solder ball pitch of less than 1 mm. In this case, the substrate may be a printed circuit board (PCB) or a polyimide substrate.

The soft element may be formed on substantially the entire surface or a portion of at least one side of at least one of the semiconductor chips. The soft element may also be formed on substantially the entire upper surface or an upper portion of the uppermost one of the semiconductor chips.

Any soft element may be used provided that it is more elastic and flexible than the mold resin. In particular, the soft element may be made of an elastomer or an epoxy resin. The elastomer may be polyimide, polyketone, polyether ketone, polyether sulfone, polyethylene terephthalate, fluoroethylene propylene copolymer, cellulose, triacetate, silicon, or rubber. Although both of the soft element and the mold resin is made of an epoxy resin, since the epoxy resin for the mold resin is mixed with an additive such as a filler, a fire retardant, a hardener, a release agent, and a pigment, the mold resin has a low thermal expansion coefficient and a hard strength.

Such a multi-chip package may be manufactured as follows. First, two or more semiconductor chips are vertically stacked on a substrate using an adhesive. Bond pads of the semiconductor chips and bond fingers of the substrate are bonded with bonding wires formed of a material such as gold. Then, a soft element is formed on at least a side of at least one of the semiconductor chips. The soft element is formed by an appropriate method according to characteristics of the soft element. For example, when the soft element is made of a viscous material, the viscous material is dispensed, spin coated, roller coated, or shower sprayed, followed by a drying process. When the soft element is in a sheet form, direct attachment of the sheet is used. The soft element may cover the gold wires and contact portions of the gold wires with the bond pads and the bond fingers. Then, the semiconductor chips and the soft element are encapsulated with a mold resin.

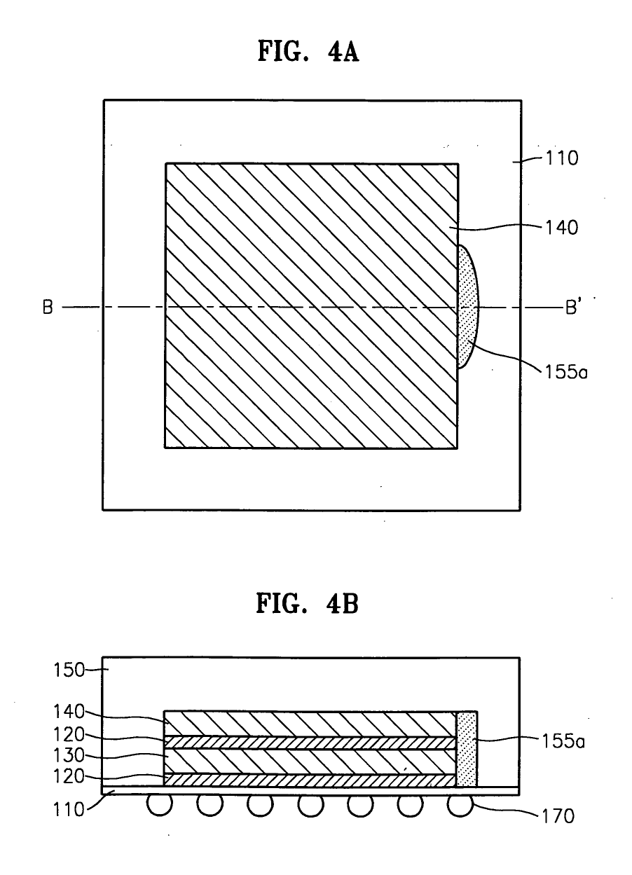

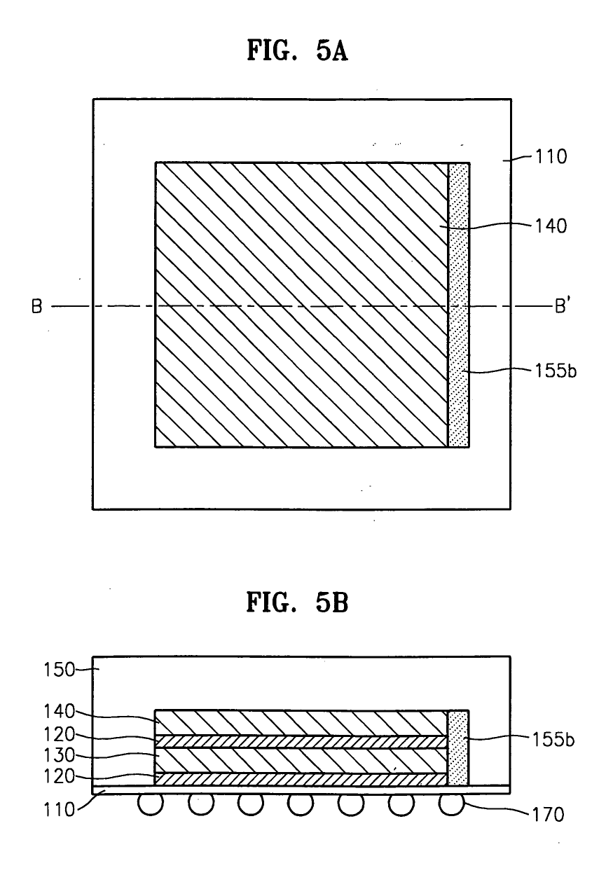

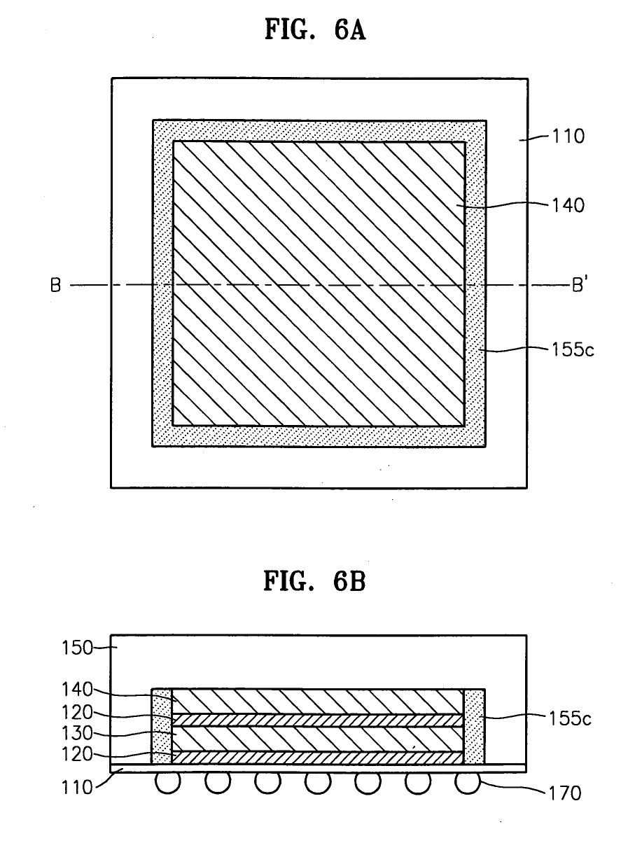

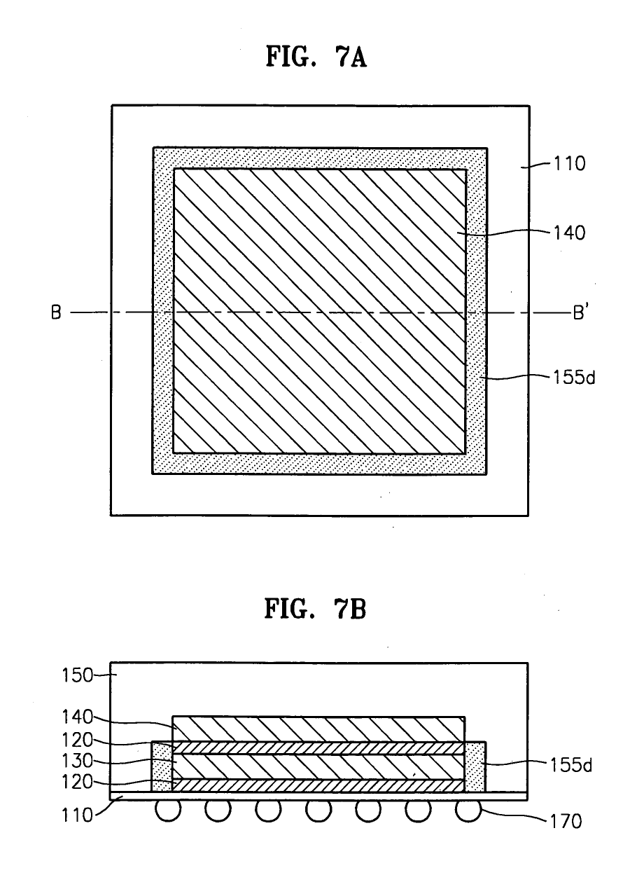

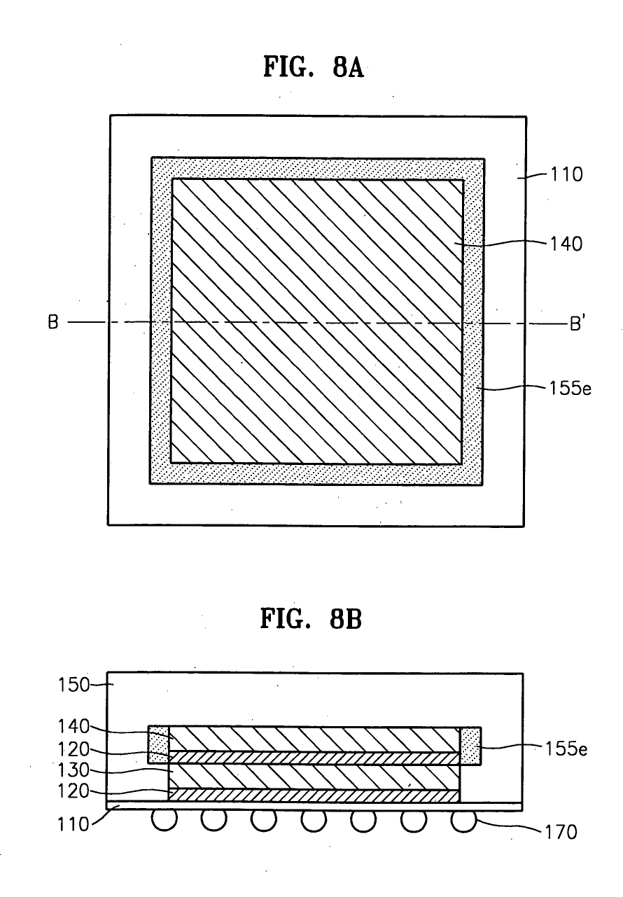

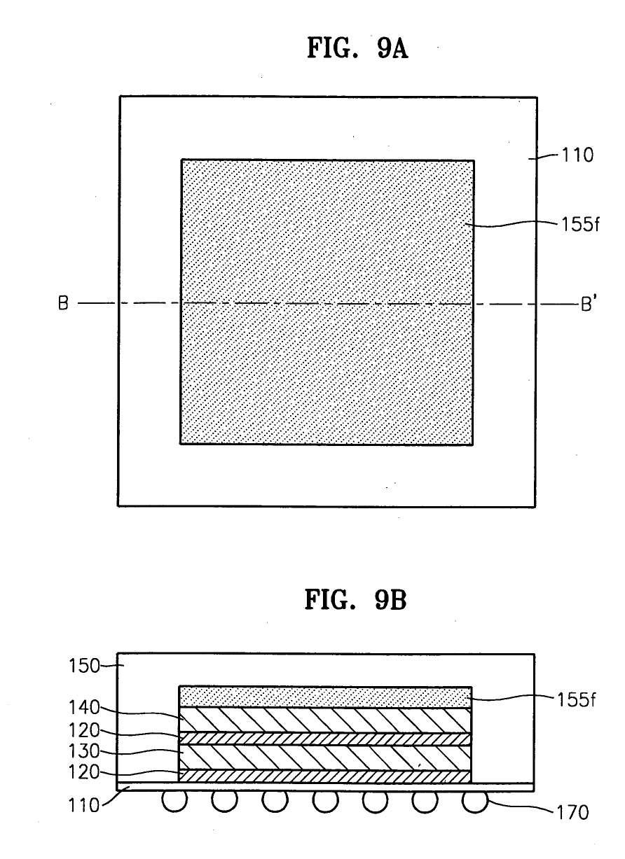

FIGS. 4 through 9 illustrate various examples of a soft element formed on an interface between semiconductor chips and a mold resin. FIG. 4A is a schematic plan view illustrating semiconductor chips mounted on a substrate according to some embodiments of the invention and FIG. 4B is a cross-cross-sectional view taken along line B-B′ of FIG. 4A. FIG. 5A is a schematic plan view illustrating semiconductor chips mounted on a substrate according to some other embodiments of the invention and FIG. 5B is a cross-cross-sectional view taken along line B-B′ of FIG. 5A. FIG. 6A is a schematic plan view illustrating semiconductor chips mounted on a substrate according to some embodiments of the invention and FIG. 6B is a cross-cross-sectional view taken along line B-B′ of FIG. 6A. FIG. 7A is a schematic plan view illustrating semiconductor chips mounted on a substrate according to some other embodiments of the invention and FIG. 7B is a cross-cross-sectional view taken along line B-B′ of FIG. 7A. FIG. 8A is a schematic plan view illustrating semiconductor chips mounted on a substrate according to some embodiments of the invention and FIG. 8B is a cross-cross-sectional view taken along line B-B′ of FIG. 8A. FIG. 9A is a schematic plan view illustrating semiconductor chips mounted on a substrate according to some other embodiments of the invention and FIG. 9B is a cross-cross-sectional view taken along line B-B′ of FIG. 9A.

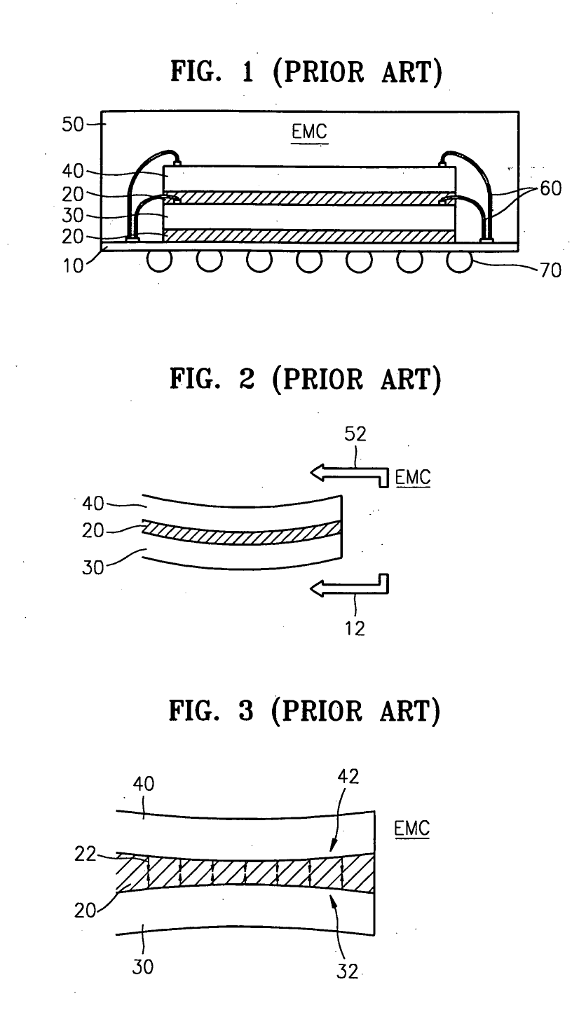

Each package illustrated in FIGS. 4 through 9 is obtained by vertically stacking a first chip 130 and a second chip 140, both of which are semiconductor chips, on a substrate 110 using an adhesive 120 and then encapsulating the stacked structure with a mold resin 150. A reference numeral 170 represents solder balls used as terminals for connecting the package to the external circuit. In order to obtain a FBGA package, the solder balls 170 have a pitch of less than 1 mm. The substrate 110 is a PCB or a polyimide substrate with a thickness as thin as 0.21 mm. For the sake of simplicity, the gold wires as shown in FIG. 1 are omitted.

First, FIG. 4 shows a soft element 155a formed on a portion of a side of the first chip 130 and the second chip 140. The side portion of the first and second chips 130 and 140 is free from the constrictive force of the mold resin 150, thereby increasing the vertical mobility of the first and second chips 130 and 140 upon cooling.

FIG. 5 shows a soft element 155b formed on substantially the entire surface of a side of the first and second chips 130 and 140. The area of the first and second chips 130 and 140 that directly contact with the mold resin 150 is smaller than that of FIG. 4. Therefore, the mobility of the first and second chips 130 and 140 is even further increased.

The soft element may also be formed on a portion or substantially the entire surface of each of two or more sides of the first and second chips 130 and 140. For example, FIG. 6 shows a soft element 155c formed on substantially the entire surface of each of four sides of the first and second chips 130 and 140. In particular, it is preferable to cover all contact portions of the gold wires including the bond pads and the bonding wires, with the soft element 155c.

In addition, the soft element may be formed on sides of one of the first and second chips 130 and 140. FIG. 7 illustrates a soft element 155d formed on sides of the first chip 130, i.e., a bottom chip. FIG. 8 illustrates a soft element 155e formed on sides of the second chip 140, i.e., a top chip. Even though only the mobility of one of the first and second chips 130 and 140 is increased, the other chip undergoes a lower level of stress.

The soft element may also be formed on substantially the entire upper surface or an upper portion of the uppermost chip. FIG. 9 illustrates a soft element 155f formed on substantially the entire upper surface of the second chip 140.

As described above, if a soft element that is more elastic and flexible than a mold resin is formed on at least a portion of an interface between semiconductor chips and the mold resin, regardless of the position of the soft element, the vertical mobility of the semiconductor chips may be increased. Therefore, even when there is a thermal expansion coefficient difference between the adhesive and the mold resin, a stress applied to the chips is minimized and local deformation of the chips is prevented, thereby preventing chip crack.

Hereinafter, embodiments of the invention will be described more specifically by experimental examples. Contents not disclosed herein can be derived by ordinary persons skilled in the art, and thus, the detailed descriptions thereof are omitted.

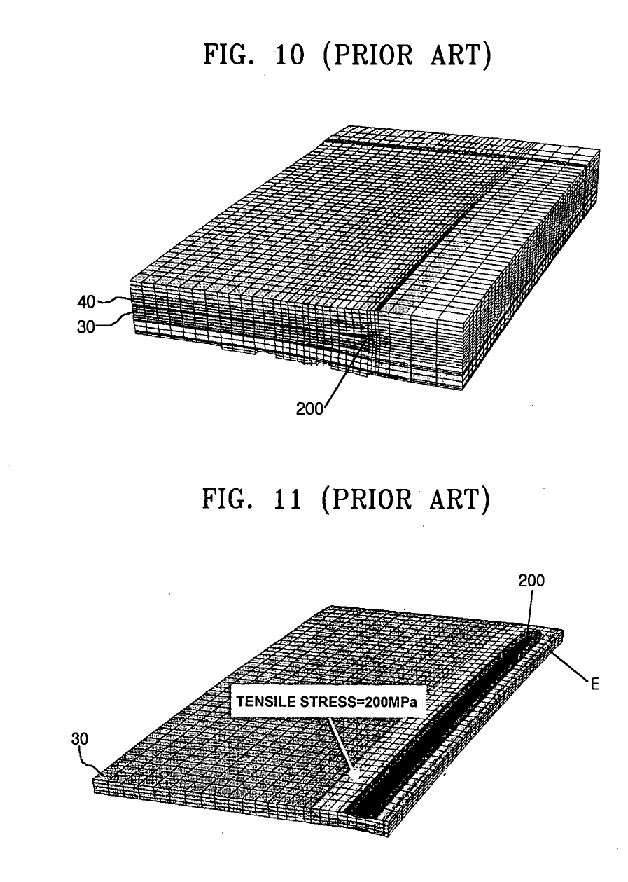

FIGS. 10 through 13 are perspective views illustrating stress simulation results of a conventional multi-chip package and a multi-chip package of the present invention. Simulation was carried out using a finite element analysis software program produced by ABAQUS, Inc., a well-known product for evaluating the physical properties of packages in the package industry. FIGS. 10 through 13 show inner stress distribution of a package when the package is cooled from 175° C. to −55° C. A darker area represents higher levels of tensile stress or compressive stress.

First, FIG. 10 depicts a stress simulation result of the multi-chip package of FIG. 1. The specific conditions of the simulation were set as follows: a thickness of the substrate 10 was 270 μm, a thickness of the adhesive 20 between the substrate 10 and the first chip 30 was 60 μm, a thickness of each of the first and second chips 30 and 40 was 170 μm, a thickness of the adhesive 20 between the first chip 30 and the second chip 40 was 120 μm, a thickness of a solder mask (not shown) to which the solder balls 70 were adhered was 33 μm, and a thickness of the EMC 50 was 700 μm. The standard area of the package was 9.5 mm×15.5 mm and the standard area of each of the first and second chips 30 and 40 was 7.12 mm×14.18 mm. The physical properties of the individual constitutional elements are as presented in Table 1 below.

TABLE 1

| | | Elastic | |
|---|---|---|---|
| | Tg | modulus | Thermal expansion |
| Section | (° C.) | (GPa) | coefficient (ppm) |
| Adhesive 20 between | 42 | 0.64 | 48/140 |
| substrate 10 and first chip 30 | | | |
| First chip 30 | — | 170 | 2.6 |
| Adhesive 20 between | 40 | 1.3/0.1 | 70/200 |
| first chip 30 and second chip 40 | | | |
| Second chip 40 | — | 170 | 2.6 |
| EMC 50 | 140 | 24/5 | 15/45 |
| Solder mask | 105 | 3 | 60/140 |

In Table 1, Tg indicates a glass transition temperature, and a numerical value represented as xx/yy indicates the thermal expansion coefficients above and below the glass transition temperature, where the xx indicates the thermal expansion coefficient below the glass transition temperature and yy the thermal expansion coefficient above the glass transition temperature.

As shown in FIG. 10, serious vertical deformation 200 occurred between the first chip 30 and the second chip 40.

FIG. 11 depicts only the stress simulation result of the first chip 30 of FIG. 10. As shown in FIG. 11, a tensile stress of 200 MPa (200,000,000 Pa or 200,000,000 N/m²) was concentrated on an inner portion 200 from an edge E of the first chip 30. This results from strong constrictive force of the EMC 50 that inhibits deformation of the edge portions of the first and second chips 30 and 40 upon cooling of the package.

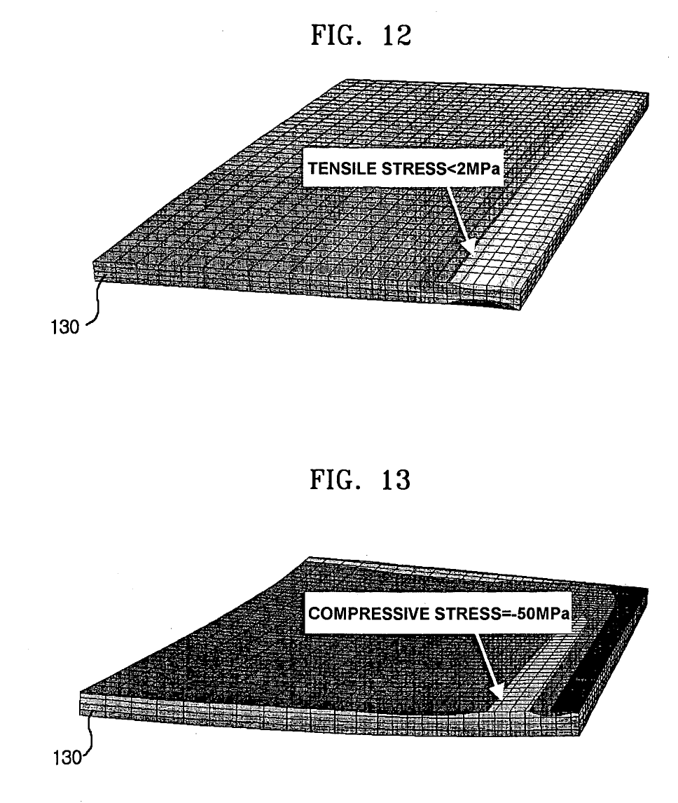

FIG. 12 depicts the stress simulation result of the first chip 130 in the multi-chip package of FIG. 8. The specific conditions of the simulation were the same as those of FIG. 10 except that the soft element 155e was formed. That is, a thickness of the substrate 110 was 270 μm, a thickness of the adhesive 120 between the substrate 110 and the first chip 130 was 60 μm, a thickness of each of the first and second chips 130 and 140 was 170 μm, a thickness of the adhesive 120 between the first chip 130 and the second chip 140 was 120 μm, a thickness of a solder mask (not shown) to which the solder balls 170 were adhered was 33 μm, and a thickness of the mold resin 150 was 700 μm. The standard area of the package was 9.5 mm×15.5 mm and the standard area of each of the first and second chips 130 and 140 was 7.12 mm×14.18 mm. The physical properties of the individual constitutional elements are as presented in Table 2 below.

TABLE 2

| | | Elastic | |
|---|---|---|---|
| | Tg | modulus | Thermal expansion |
| Section | (° C.) | (GPa) | coefficient (ppm) |
| Adhesive 120 between | 42 | 0.64 | 48/140 |
| substrate 110 and first chip 130 | | | |
| First chip 130 | — | 170 | 2.6 |
| Adhesive 120 between | 40 | 1.3/0.1 | 70/200 |
| first chip 130 and | | | |
| second chip 140 | | | |
| Second chip 140 | — | 170 | 2.6 |
| Mold resin 150 | 140 | 24/5 | 15/45 |
| Solder mask | 105 | 3 | 60/140 |
| Soft element 155e | | 1 | 50 |

As in Table. 1, Tg indicates a glass transition temperature, and a numerical value represented as xx/yy indicates the physical property value below Tg/the physical property value above Tg.

Due to the soft element 155e formed on the sides of the second chip 140, a tensile stress of less than 2 MPa was measured. This corresponds to about 1/100 of the tensile stress of the first chip 30 with no soft element of FIG. 11.

FIG. 13 depicts the stress simulation result of the first chip 130 in the multi-chip package of FIG. 6. Due to the soft element 155c formed on the fourth sides of the first and second chips 130 and 140, little tensile stress was measured. Rather, the first chip 130 experienced a compressive stress of about −150 MPa.

Embodiments of the invention will now be described in a non-limiting way.

According to an embodiment of the invention, there is provided a multi-chip package in which two or more semiconductor chips vertically mounted on a substrate with an adhesive are encapsulated with a mold resin, the mold resin also encapsulating a soft element that is more elastic and flexible than the mold resin and located at an interface between the semiconductor chips and the mold resin.

According to another embodiment of the invention, there is provided a method of manufacturing a multi-chip package, including: vertically stacking two or more semiconductor chips on a substrate using an adhesive; bonding bond pads of the semiconductor chips and bond fingers of the substrate with gold wires; forming a soft element on at least a side of at least one of the semiconductor chips; and encapsulating the semiconductor chips and the soft element using a mold resin.

As is apparent from the above descriptions, embodiments of the invention are made in view of the fact that the mobility of semiconductor chips upon cooling is constricted due to the load of adhesive applied to the semiconductor chips. In this regard, a soft element is formed around the semiconductor chips to ensure the vertical mobility of the semiconductor chips. The soft element mitigates the constrictive force of a mold resin on the semiconductor chips, thereby enabling the relatively free vertical movement of the semiconductor chips. In other words, the vertical mobility of the chips increases relative to the decreased portion of the chips that are in direct contact with the mold resin. Even though there is a thermal expansion coefficient difference between the adhesive and the mold resin, a stress applied to the semiconductor chips upon cooling is minimized, thereby preventing local chip deformation, stress concentration on the chips, and chip crack.

Consequently, a factor that causes damage to chips can be removed, thereby enhancing the characteristics and reliability of a semiconductor device. Furthermore, productivity is increased and a production cost is reduced.

While the invention has been particularly shown and described with reference to exemplary embodiments thereof, it will be understood by those of ordinary skill in the art that various changes in form and details may be made therein without departing from the spirit and scope of the invention as defined by the following claims.

1. A multi-chip package comprising:
at least two semiconductor chips vertically mounted on a substrate and encapsulated with a mold resin; and
a soft element located at an interface between at least one of the at least two semiconductor chips and the mold resin, the soft element being more elastic and flexible than the mold resin.

2. The multi-chip package of claim 1, wherein the soft element contacts substantially the entire surface of at least one side of the at least one of the at least two semiconductor chips.

3. The multi-chip package of claim 1, wherein the soft element contacts a portion of at least one side of the at least one of the at least two semiconductor chips.

4. The multi-chip package of claim 1, wherein the soft element contacts substantially the entire upper surface of an uppermost chip of the at least two semiconductor chips.

5. The multi-chip package of claim 1, wherein the soft element contacts a portion of an upper surface of an uppermost chip of the at least two semiconductor chips.

6. The multi-chip package of claim 1, further comprising an adhesive applied for adhesion between the substrate and the at least two semiconductor chips, wherein the soft element is configured to increase vertical mobility of the semiconductor chips against a load of the adhesive applied to the semiconductor chips upon cooling.

7. The multi-chip package of claim 1, wherein the soft element comprises one selected from the group consisting of an elastomer and an epoxy resin.

8. The multi-chip package of claim 1, the package further comprising:
solder balls as terminals for connecting the package to an external circuit.

9. The multi-chip package of claim 1, wherein the substrate comprises one selected from the group consisting of a printed circuit board (PCB) substrate and a polyimide substrate.

10. A device comprising:
at least two semiconductor chips stacked on a substrate;
a soft element formed on a surface of at least one of the at least two semiconductor chips; and
an encapsulant covering the at least two semiconductor chips and the soft element, the soft element configured to reduce the constrictive force of the encapsulant on the surface.

11. The device of claim 10, wherein the surface comprises substantially the entire surface that is contained by a single plane.

12. The device of claim 10, wherein the surface comprises a part of substantially the entire surface that is contained by a single plane.

13. The device of claim 10, wherein the encapsulant comprises one selected from the group consisting of an elastomer and an epoxy resin.

14. A method of manufacturing a multi-chip package, comprising:
vertically stacking at least two semiconductor chips on a substrate;
bonding a bond pad on at least one of the at least two semiconductor chips to a bond finger on the substrate with a bonding wire;
forming a soft element on at least one side of at least one of the at least two semiconductor chips; and
encapsulating the at least two semiconductor chips and the soft element using a mold resin.

15. The method of claim 14, wherein forming the soft element comprises:
forming the soft element on substantially the entire surface of the at least one side.

16. The method of claim 14, wherein forming the soft element comprises:
forming the soft element on a portion of the at least one side.

17. The method of claim 14, wherein forming the soft element comprises:
forming the soft element on substantially the entire upper surface of an uppermost one of the at least two semiconductor chips.

18. The method of claim 14, wherein forming the soft element comprises:
forming the soft element on a portion of an upper surface of an uppermost one of the at least two semiconductor chips.

19. The method of claim 14, wherein forming the soft element comprises:
forming the soft element to cover the bonding wire, to cover a contact area between the bonding wire and the bond pad, and to cover a contact area between the bonding wire and the bond finger.

20. The method of claim 14, wherein the soft element comprises one selected from the group consisting of an elastomer or an epoxy resin.
